(19) United States
(12) Patent Application Publication
(10) Pub. No.: US 2025/0063254 A1
(43) Pub. Date: Feb. 20, 2025

(54) IMAGING ELEMENT AND ELECTRONIC APPARATUS

(71) Applicant: SONY SEMICONDUCTOR SOLUTIONS CORPORATION, KANAGAWA (JP)

(72) Inventors: TOSHIHISA MAKIHIRA, KANAGAWA (JP); HIDEKI TANAKA, KANAGAWA (JP)

(21) Appl. No.: 18/725,086

(22) PCT Filed: Nov. 28, 2022
(86) PCT No.: PCT/JP2022/043667

§ 371 Date: Jun. 27, 2024

(30) Foreign Application Priority Data
Jan. 7, 2022 (JP) 2022-001397

(51) Int. Cl. H04N 23/67; G02B 3/00; G02B 5/20; H04N 23/55; H04N 23/84; H04N 25/13; H04N 25/447; H04N 25/78

(52) U.S. Cl. CPC H04N 23/672; H04N 23/55; H04N 23/843; H04N 25/134; H04N 25/447; H04N 25/78; G02B 3/0056; G02B 5/201

(57) ABSTRACT

An imaging element of the present technology includes a first pixel block having a plurality of pixels including color filters of a same first color and a second pixel block having a plurality of pixels including color filters of a second color different from the first pixel block, the number of pixels of the second pixel block being different from the number of pixels of the first pixel block. The first pixel block and the second pixel block have a configuration in which a charge-voltage conversion unit and succeeding pixel constituent elements are among a plurality of pixels. The imaging element further includes a signal amount adjustment unit that adjusts an output signal amount output from each pixel of the first pixel block and the second pixel block. The signal amount adjusting unit adjusts the output signal amount so that the output signal amount concerning the first color and the output signal amount concerning the second color match.

### TECHNICAL FIELD

The present technology relates to an imaging element. Specifically, the present technology relates to an imaging element having a pixel structure for obtaining an image plane phase difference, and an electronic apparatus having the imaging element.

### BACKGROUND ART

In an electronic apparatus having an imaging function represented by a digital still camera, an autofocus system of automatically focusing on a subject is adopted. One type of autofocus system is a phase difference system, and one type of phase difference system is an image plane phase difference system (see, for example, Patent Document 1).

### CITATION LIST

### Patent Document

Patent Document 1: WO 2016/098640 A

### SUMMARY OF THE INVENTION

### Problems to be Solved by the Invention

The above-described conventional technique discloses an imaging element including a normal pixel for obtaining a pixel signal constituting a captured image and a phase difference detection pixel for obtaining an image plane phase difference. Since an imaging element is desired to be high in quality of a captured image, it is anticipated that a pixel size will be reduced along with an increase in the number of pixels in the future. According to the above-described conventional technology, the phase difference detection pixel includes two pixels adjacent to each other, and has, as a basic configuration, a pixel structure in which one on-chip lens is provided for the two pixels. Therefore, there is a demand for an imaging element that can contribute to realization of high-accuracy autofocus while maintaining the basic pixel structure of the phase difference detection pixel even when a pixel size is reduced along with improvement in image quality of a captured image.

The present technology has been made in view of such a circumstance, and an object of the present technology is to contribute to realization of high-accuracy autofocus while maintaining a basic configuration of a phase difference detection pixel even when a pixel size is reduced along with improvement in image quality of a captured image.

### Solutions to Problems

The present technology was made in order to solve the above problem, and a first aspect of the present technology is an imaging element including: a first pixel block having a plurality of pixels including color filters of a same first color; and a second pixel block having a plurality of pixels including color filters of a same second color that is different from the first pixel block, the number of pixels of the second pixel block being different from the number of pixels of the first pixel block, in which the first pixel block and the second pixel block each have a plurality of pixel pairs each including two pixels, a plurality of lenses is provided at positions corresponding to the plurality of pixel pairs, the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels, the imaging element further includes a signal amount adjustment unit that adjusts output signal amounts output from the pixels of the first pixel block and the second pixel block, and the signal amount adjustment unit adjusts the output signal amounts so that an output signal amount concerning the first color output from the first pixel block and an output signal amount concerning the second color output from the second pixel block match. This produces an effect of contributing to realization of high-accuracy autofocus while maintaining a basic configuration of a phase difference detection pixel even if a pixel size is reduced along with improvement of image quality of a captured image, and an effect of obtaining an output signal amount proportional to an exposure time even if the number of pixels of a pixel block varies from one color to another. Here, “matching” includes not only strict matching but also substantial matching, and existence of various variations caused by design or manufacturing is allowed.

Furthermore, in the first aspect, the signal amount adjustment unit may adjust the output signal amount concerning the first color output from the first pixel block and the output signal amount concerning the second color output from the second pixel block so that a smaller one of the output signal amounts matches a larger one of the output signal amounts. This produces an effect of absorbing a difference in output signal amount among colors.

Furthermore, in the first aspect, in a first drive mode in which signals of the pixels of the first pixel block and the second pixel block are individually read and a second drive mode in which signals of the two pixels of the pixel pair are added and the added signals are read, the signal amount adjustment unit may adjust the output signal amounts so that the output signal amount concerning the second color output from the second pixel block matches the output signal amount concerning the first color output from the first pixel block. This produces an effect of absorbing a difference in output signal amount among colors in the first drive mode and the second drive mode.

Furthermore, in the first aspect, in a third drive mode in which signals of all the pixels of the first pixel block and the second pixel block are added and the added signals are read, the signal amount adjustment unit may adjust the output signal amounts so that the output signal amount concerning the first color output from the first pixel block matches the output signal amount concerning the second color output from the second pixel block. This produces an effect of absorbing a difference in output signal amount among colors in the third drive mode.

Furthermore, in the first aspect, the signal amount adjustment unit may adjust the output signal amounts by digital gain adjustment in a digital region after conversion of an analog signal output from each of the pixels of the first pixel block and the second pixel block into a digital signal. This produces an effect of performing the processing of absorbing a difference in output signal amount among colors in the digital region.

Furthermore, in the first aspect, the signal amount adjustment unit may adjust the output signal amounts of the colors by analog gain adjustment in an analog region before conversion of an analog signal output from each of the pixels of the first pixel block and the second pixel block into a digital signal. This produces an effect of performing the processing of absorbing a difference in output signal amount among colors in the analog region.

Furthermore, in the first aspect, an analog-digital conversion unit that converts an analog signal into a digital signal may be a single-slope analog-digital conversion unit that uses, as a signal for reference in analog-digital conversion, a reference signal of a ramp wave whose level changes at a predetermined slope with passage of time, and the signal amount adjustment unit may perform the analog gain adjustment by changing the slope of the reference signal of the ramp wave. This produces an effect of performing the processing of absorbing a difference in output signal amount among colors by changing the slope of the reference signal of the ramp wave.

Furthermore, in the first aspect, the two pixels may be arranged side by side in a first direction, and in each of the first pixel block and the second pixel block, two of the pixel pairs that are arranged in a second direction intersecting the first direction may be arranged to be shifted in the first direction. This produces an effect that pixel arrangement in a pixel array unit can be made dense.

Furthermore, a second aspect of the present technology is an imaging element including a first pixel block having a plurality of pixels including color filters of a same first color; a second pixel block having a plurality of pixels including color filters of a same second color that is different from the first pixel block, the number of pixels of the second pixel block being different from the number of pixels of the first pixel block; and an analog-digital conversion unit that converts an analog signal output from each pixel of the first pixel block and the second pixel block into a digital signal, in which the first pixel block and the second pixel block each have a plurality of pixel pairs each including two pixels, a plurality of lenses is provided at positions corresponding to the plurality of pixel pairs, the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels, the analog-digital conversion unit is a single-slope analog-digital conversion unit that uses, as a signal for reference in analog-digital conversion, a reference signal of a ramp signal given from a reference signal generation unit, a plurality of reference signal generation units that generate reference signals of ramp waves having different slopes are provided as the reference signal generation unit, the imaging element further includes a signal amount adjustment unit that adjusts output signal amounts output from the pixels of the first pixel block and the second pixel block, and the signal amount adjustment unit adjusts the output signal amounts so that an output signal amount concerning the first color output from the first pixel block and an output signal amount concerning the second color output from the second pixel block match on the basis of the reference signals of the ramp waves having the different slopes generated by the plurality of reference signal generation units. This produces an effect of contributing to realization of high-accuracy autofocus while maintaining a basic configuration of a phase difference detection pixel even if a pixel size is reduced along with improvement of image quality of a captured image, and an effect of obtaining an output signal amount proportional to an exposure time even if the number of pixels of a pixel block varies from one color to another.

Furthermore, in the second aspect, the plurality of reference signal generation units may include a reference signal generation unit for adjusting the output signal amount concerning the first color output from the first pixel block and a reference signal generation unit for adjusting the output signal amount concerning the second color output from the second pixel block. This produces an effect of performing the processing of absorbing a difference between output signal amounts of the colors output from the pixel blocks by adjusting the slopes of the reference signals of the ramp waves generated by the two reference signal generation units.

Furthermore, a third aspect of the present technology is an electronic apparatus including an imaging element including: a first pixel block having a plurality of pixels including color filters of a same first color; and a second pixel block having a plurality of pixels including color filters of a same second color that is different from the first pixel block, the number of pixels of the second pixel block being different from the number of pixels of the first pixel block, in which the first pixel block and the second pixel block each have a plurality of pixel pairs each including two pixels, a plurality of lenses is provided at positions corresponding to the plurality of pixel pairs, the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels, the imaging element further includes a signal amount adjustment unit that adjusts output signal amounts output from the pixels of the first pixel block and the second pixel block, and the signal amount adjustment unit adjusts the output signal amounts so that an output signal amount concerning the first color output from the first pixel block and an output signal amount concerning the second color output from the second pixel block match. This produces an effect of contributing to realization of high-accuracy autofocus while maintaining a basic configuration of a phase difference detection pixel even if a pixel size is reduced in an imaging element along with improvement of image quality of a captured image, and an effect of obtaining an output signal amount proportional to an exposure time even if the number of pixels of a pixel block varies from one color to another.

### BRIEF DESCRIPTION OF DRAWINGS

FIG. 1 is a block diagram illustrating a configuration example of an imaging element according to the first embodiment of the present technology.

FIG. 2 is a plan view illustrating an example of pixel arrangement in a pixel array unit of the imaging element according to the first embodiment.

FIG. 3 is a cross-sectional view illustrating an example of a schematic cross-sectional structure of the pixel array unit of the imaging element according to the first embodiment.

FIG. 4 is a circuit diagram illustrating an example of a circuit configuration of a green (Gr) pixel block illustrated in FIG. 2.

FIG. 5 is a circuit diagram illustrating an example of a circuit configuration of a red (R) pixel block illustrated in FIG. 2.

FIG. 6 is a block diagram illustrating a configuration example of a readout unit of the imaging element according to the first embodiment.

FIG. 7 is a diagram illustrating an example of a structure of an image signal Spic output from the imaging element according to the first embodiment.

FIG. 8 is a perspective view schematically illustrating a flat-type semiconductor chip structure and a stack-type semiconductor chip structure.

FIG. 9 is a block diagram illustrating a configuration example of a signal amount adjustment unit of the imaging element according to the first embodiment.

FIG. 10 is a diagram for explaining adjustment of output signal amounts in a case of an all-pixel readout mode and an AF mode.

FIG. 11 is a diagram for explaining adjustment of output signal amounts in a case of an all-pixel addition mode.

FIG. 12 is a circuit diagram illustrating a configuration example of a digital-analog conversion unit in the second embodiment of the present technology.

FIG. 13 is a waveform diagram illustrating a timing relationship among a waveform of a reference signal RAMP in the case of high gain, a waveform of a reference signal RAMP of low gain, a waveform of a signal line VSL, and a clock of a counter.

FIG. 14 is a block diagram illustrating a configuration example of an imaging device which is an example of an electronic apparatus to which the present technology is applied.

FIG. 15 illustrates an example of fields to which the embodiments of the present technology are applied.

FIG. 16 is a block diagram illustrating a schematic configuration example of a vehicle control system.

FIG. 17 is an explanatory diagram illustrating an example of an installation position of an imaging section.

### MODE FOR CARRYING OUT THE INVENTION

Hereinafter, modes for carrying out the present technology (hereinafter, referred to as embodiments) are described. The description will be given in the following order.
1. First embodiment (control of absorbing difference in output signal amount among colors: example in digital gain correction processing)
2. Second embodiment (control of absorbing difference in output signal amount among colors: example in analog gain correction processing)
3. Modifications
4. Example of application to electronic apparatus
5. Example of application of embodiments of present technology
6. Example of application to mobile body
7. Configuration that can be taken by present technology

### 1. First Embodiment

One example of an imaging element of the present technology is a complementary metal oxide semiconductor (CMOS) image sensor, which is a type of an X-Y address system imaging element. The CMOS image sensor is an imaging element fabricated by applying or partially using a CMOS process.

### [Configuration Example of Imaging Element]

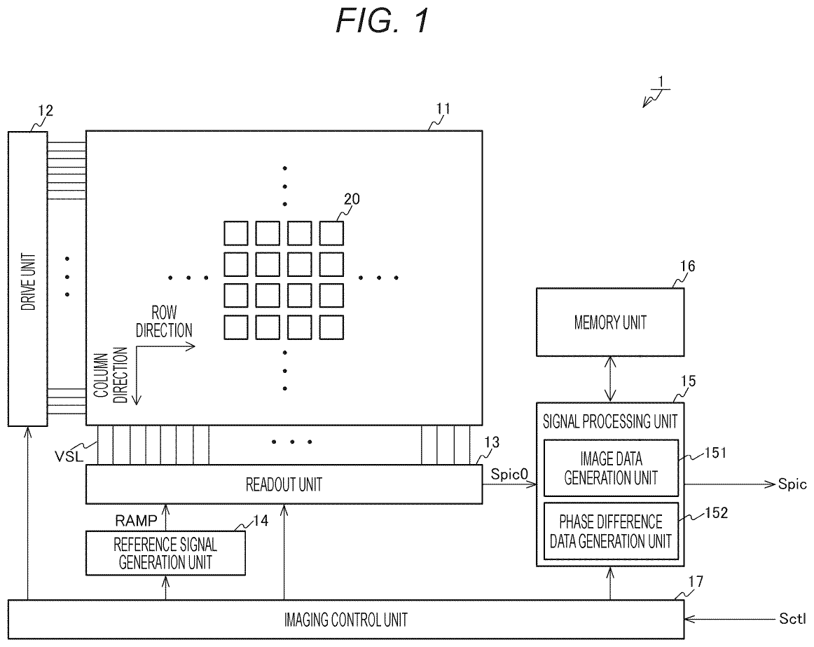

FIG. 1 is a block diagram illustrating a configuration example of an imaging element according to the first embodiment of the present technology. This imaging element 1 includes a pixel array unit 11, a drive unit 12, a readout unit 13, a reference signal generation unit 14, a signal processing unit 15, a memory unit (data storage unit) 16, and an imaging control unit 17.

The pixel array unit 11 has pixels (pixel circuits) 20 which are two-dimensionally arranged in a row direction and a column direction, that is, in a matrix. Each of the pixels 20 includes a photoelectric conversion unit (photoelectric conversion element). Here, the row direction refers to a direction in which the pixels 20 in a pixel row are arrayed, and the column direction refers to a direction in which the pixels 20 in a pixel column are arrayed. The pixel 20 performs photoelectric conversion to generate and accumulate a photoelectric charge corresponding to an amount of received light. The pixel 20 generates a signal SIG including a pixel voltage Vpix according to the amount of received incident light.

The drive unit 12 includes a shift register and an address decoder, and performs drive of controlling scanning for the pixel row and an address of the pixel row on the basis of a timing control signal supplied from the imaging control unit 17 when selecting each pixel 20 of the pixel array unit 11. Under the drive performed by the drive unit 12, the signal SIG including the pixel voltage Vpix is output from each pixel 20 of the pixel array unit 11.

The readout unit 13 includes, for example, a single-slope analog-digital conversion unit to be described later, and performs analog-digital conversion (AD conversion) on the signal SIG including the pixel voltage Vpix, which is read from each pixel 20 of the pixel array unit 11 via a signal line VSL, under control of the imaging control unit 17. The readout unit 13 outputs the signal after the analog-digital conversion as an image signal Spic0.

The reference signal generation unit 14 generates a reference signal RAMP used as a signal for reference in the analog-digital conversion in the single-slope analog-digital conversion unit of the readout unit 13. The reference signal RAMP is a so-called ramp wave signal whose level (voltage) changes (for example, monotonically decreases) at a predetermined slope with passage of time.

Under the control of the imaging control unit 17, the signal processing unit 15 performs predetermined signal processing on the image signal Spic0 supplied from the readout unit 13 and outputs an image signal Spic thus obtained. The signal processing unit 15 includes an image data generation unit 151 and a phase difference data generation unit 152.

In the signal processing unit 15, the image data generation unit 151 is configured to generate image data DP indicating a captured image by performing predetermined image processing on the basis of the image signal Spic0. The phase difference data generation unit 152 is configured to generate phase difference data DE indicating an image plane phase difference by performing predetermined image processing on the basis of the image signal Spic0.

The signal processing unit 15 outputs the image signal Spic including the image data DP generated by the image data generation unit 151 and the phase difference data DF generated by the phase difference data generation unit 152.

The memory unit (data storage unit) 16, for example, temporarily memorizes (stores) data necessary for signal processing when the signal processing is performed by the signal processing unit 15.

The imaging control unit 17 generates various timing signals, clock signals, control signals, and the like on the basis of a control signal Sct1 given from an outside, and performs drive control of the drive unit 12, the readout unit 13, the reference signal generation unit 14, the signal processing unit 15, and the like on the basis of the generated signals, thereby controlling the operation of the imaging element 1. The imaging control unit 17 controls imaging operation of the imaging element 1 on the basis of the control signal Sct1.

### [Example of Arrangement of Pixels]

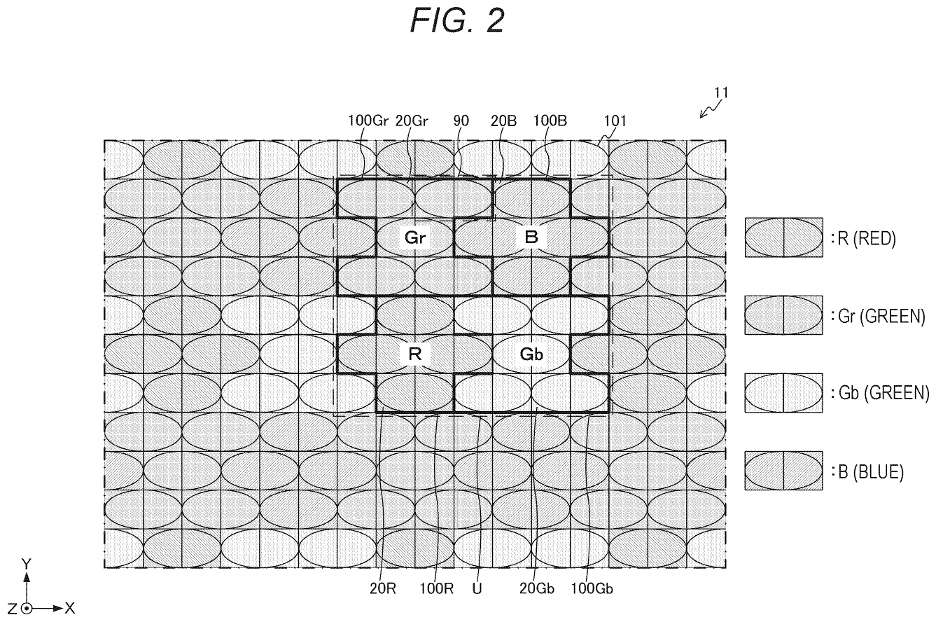

FIG. 2 is a plan view illustrating an example of arrangement of the pixels 20 in the pixel array unit 11. As illustrated in FIG. 2, the pixel array unit 11 includes a plurality of pixel blocks 100 and a plurality of lenses 101.

The plurality of pixel blocks 100 includes a pixel block 100R, a pixel block 100Gr, a pixel block 100Gb, and a pixel block 100B. In the pixel array unit 11, the plurality of pixels 20 is arranged while regarding the four pixel blocks 100 (the pixel blocks 100R, 100Gr, 100Gb, and 100B) as a unit (unit U).

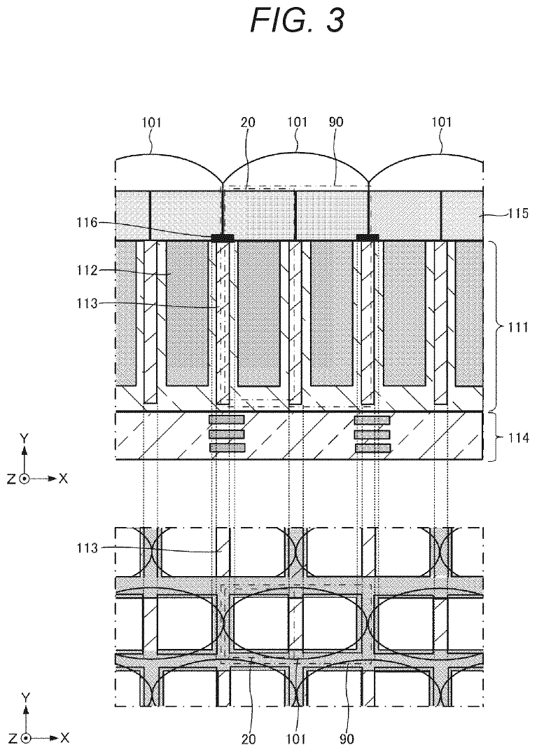

The pixel block 100R includes eight pixels 20R including a red (R) color filter 115 (see FIG. 3). The pixel block 100Gr includes ten pixels 20Gr including a green (G) color filter 115. The pixel block 100Gb includes ten pixels 20Gb including a green (G) color filter 115. The pixel block 100B includes eight pixels 20B including a blue (B) color filter 115. In FIG. 2, the differences in color among the color filters are expressed by using shading.

An arrangement pattern of the eight pixels 20R in the pixel block 100R and an arrangement pattern of the eight pixels 20B in the pixel block 100B are identical to each other. An arrangement pattern of the ten pixels 20Gr in the pixel block 100Gr and an arrangement pattern of the ten pixels 20Gb in the pixel block 100Gb are identical to each other. In the unit U, the pixel block 100Gr is arranged at the upper left, the pixel block 100R is arranged at the upper right, the pixel block 100B is arranged at the lower left, and the pixel block 100Gb is arranged at the lower right.

Arrangement of the pixel block 100R, the pixel block 100Gr, the pixel block 100Gb, and the pixel block 100B is RGB Bayer arrangement. That is, the pixel block 100R, the pixel block 100Gr, the pixel block 100Gb, and the pixel block 100B are arranged in RGB Bayer arrangement while regarding the pixel block 100 as a unit.

Note that red (R) and blue (B) are examples of a first color recited in the claims, and green (Gr, Gb) is an example of a second color recited in the claims. Furthermore, the pixel block 100R and the pixel block 100B are examples of a first pixel block recited in the claims, and the pixel block 100Gr and the pixel block 100Gb are examples of a second pixel block recited in the claims.

### [Example of Cross-Sectional Structure of Pixel Array Unit]

FIG. 3 is a cross-sectional view illustrating a schematic cross-sectional structure of the pixel array unit 11. As illustrated in FIG. 3, the pixel array unit 11 includes a semiconductor substrate 111, a semiconductor region 112, an insulating layer 113, a multilayer wiring layer 114, the color filter 115, and a light shielding film 116 in addition to the plurality of lenses 101.

The semiconductor substrate 111 is a support substrate on which the imaging element 1 is formed, and is, for example, a P-type semiconductor substrate. The semiconductor region 112 is a semiconductor region provided at a position corresponding to each of the plurality of pixels 20 in the semiconductor substrate 111, and is doped with an N-type impurity to form a photoelectric conversion unit (for example, a photodiode). The insulating layer 113 is provided at a boundary between the plurality of pixels 20 arranged side by side on the XY plane in the semiconductor substrate 111, and is a deep trench isolation (DTI) formed by an oxide film or the like in this example.

The multilayer wiring layer 114 is provided on the semiconductor substrate 111 on a surface opposite to a light incident side (lens 101 side) of the pixel array unit 11, and includes a plurality of wiring layers and an interlayer insulating film. The wiring in the multilayer wiring layer 114 is, for example, configured to connect a transistor (not illustrated) provided on the surface of the semiconductor substrate 111, and the drive unit 12 and the readout unit 13.

The color filter 115 is provided on the semiconductor substrate 111 on the light incident side of the pixel array unit 11. Here, assume that a first direction is the X direction and a second direction is the Y direction in the XY plane, the light shielding film 116 is provided so as to surround two pixels 20 arranged side by side in the X direction on the light incident side of the pixel array unit 11. Hereinafter, the two pixels 20 arranged side by side in the X direction are also referred to as a pixel pair 90.

The plurality of lenses 101 is so-called on-chip lenses, and is provided on the color filter 115 on the light incident side of the pixel array unit 11. Each of the plurality of lenses 101 is provided above the two pixels 20 (pixel pair 90) arranged side by side in the X direction. Four lenses 101 are provided above the eight pixels 20 of the pixel block 100R. Five lenses 101 are provided above the ten pixels 20 of the pixel block 100Gr. Five lenses 101 are provided above the ten pixels 20 of the pixel block 100Gb. Four lenses 101 are provided above the eight pixels 20 of the pixel block 100B.

The plurality of lenses 101 is arranged side by side in the X direction and the Y direction. The lenses 101 arranged in the Y direction are shifted by one pixel 20 in the X direction. In other words, the pixel pairs 90 arranged in the Y direction are shifted by one pixel 20 in the X direction.

With this configuration, images are shifted from each other in the two pixels 20 of the pixel pair 90 corresponding to one lens 101. The imaging element 1 generates the phase difference data DF on the basis of a so-called image plane phase difference detected by the plurality of pixel pairs 90. That is, the two pixels 20 of the pixel pair 90 corresponding to one lens 101 are phase difference detection pixels for generating the phase difference data DF on the basis of the image plane phase difference. In an electronic apparatus having an imaging function such as a digital still camera, a defocus amount is determined on the basis of the phase difference data DE, and a position of an imaging lens is moved on the basis of the defocus amount. The electronic apparatus having the imaging function can thus realize autofocus.

### [Example of Circuit Configuration of Pixel Block]

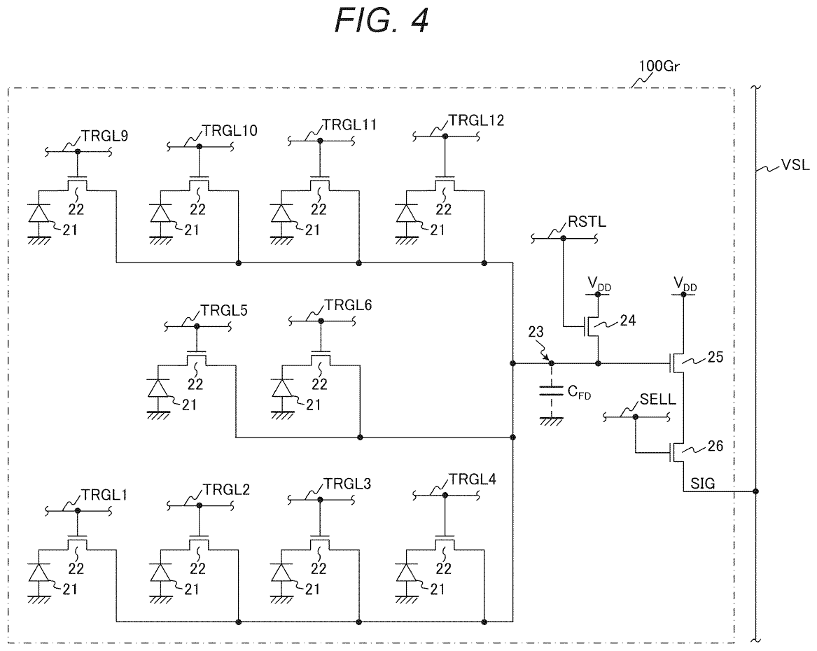

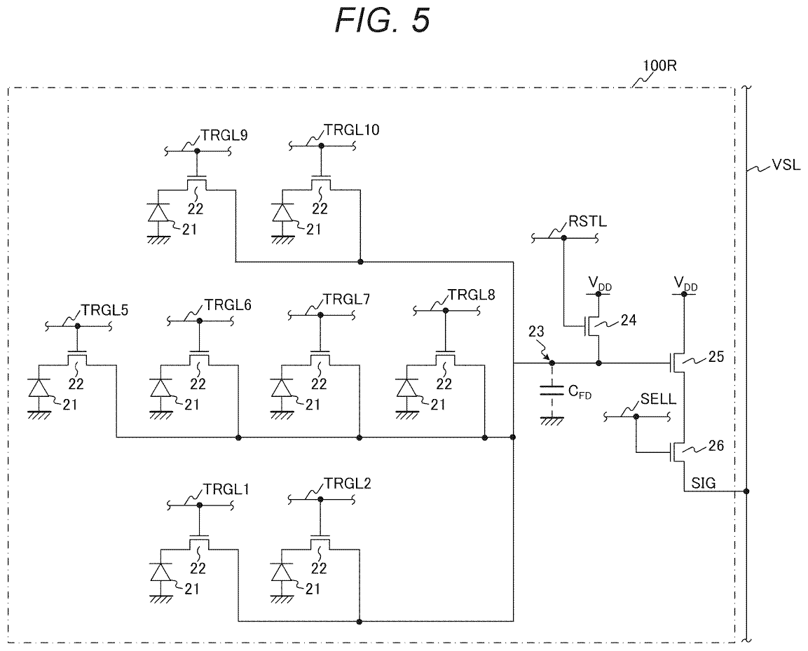

Next, an example of a circuit configuration of the pixel block 100 will be described by using the green (Gr) pixel block 100Gr having the ten pixels 20Gr and the red (R) pixel block 100R having the eight pixels 20R as examples. FIG. 4 is a circuit diagram illustrating an example of a circuit configuration of the green (Gr) pixel block 100Gr. FIG. 5 is a circuit diagram illustrating an example of a circuit configuration of the red (R) pixel block 100R.

The pixel array unit 11 includes a plurality of control lines TRGL, a plurality of control lines RSTL, a plurality of control lines SELL, and a plurality of signal lines VSL.

The control line TRGL is wired along the row direction for each pixel row of the pixel array unit 11, and one end thereof is connected to a corresponding output end of the drive unit 12. A control signal is supplied from the drive unit 12 to the control line TRGL as appropriate. The control line RSTL is wired along the row direction for each pixel row of the pixel array unit 11, and one end thereof is connected to a corresponding output end of the drive unit 12. A control signal is supplied from the drive unit 12 to the control line RSTL as appropriate.

The control line SELL is wired along the row direction for each pixel row of the pixel array unit 11, and one end thereof is connected to a corresponding output end of the drive unit 12. A control signal is supplied from the drive unit 12 to the control line SELL as appropriate. The signal line VSL is wired along the column direction for each pixel column of the pixel array unit 11, and one end thereof is connected to the readout unit 13. The signal line VSL transmits the signal SIG output from the pixel 20 to the readout unit 13.

The green (Gr) pixel block 100Gr illustrated in FIG. 4 includes ten photoelectric conversion units 21 and ten transfer transistors 22. The pixel block 100Gr further includes one charge-voltage conversion unit 23, one reset transistor 24, one amplification transistor 25, and one selection transistor 26.

Here, for example, an N-type metal oxide semiconductor (MOS) field-effect transistor can be used as the transfer transistors 22, the reset transistor 24, the amplification transistor 25, and the selection transistor 26. However, a combination of conductivity types of the transfer transistors 22, the reset transistor 24, the amplification transistor 25, and the selection transistor 26 exemplified here is only an example, and the combination is not limited to these.

The ten photoelectric conversion units 21 and the ten transfer transistors 22 correspond to the ten pixels 20Gr included in the pixel block 100Gr, respectively. Furthermore, the pixel block 100Gr has a so-called pixel-sharing pixel circuit configuration in which the charge-voltage conversion unit 23, the reset transistor 24, the amplification transistor 25, and the selection transistor 26 are shared among the ten pixels 20Gr.

The photoelectric conversion units 21 are PN-junction photodiodes (PDs). Each of the photodiodes has an anode electrode connected to a low-potential-side power supply (for example, ground), and generates an electric charge of an amount corresponding to an amount of received light and accumulates therein the generated electric charge. A cathode electrode of the photodiode 21 is connected to a source electrode of the transfer transistor 22.

A gate electrode of the transfer transistor 22 is connected to the control line TRGL, a source electrode thereof is connected to the cathode electrode of the photoelectric conversion unit 21, and a drain electrode thereof is connected to the charge-voltage conversion unit 23. The gate electrodes of the ten transfer transistors 22 are connected to different control lines TRGL among the ten control lines TRGL (in this example, control lines TRGL1 to TRGL6 and TRGL9 to TRGL 12).

The charge-voltage conversion unit 23 is capacitance C_{FD} of a floating diffusion (FD) region formed between a drain region of the transfer transistor 22 and a source region of the reset transistor 24. The charge-voltage conversion unit 23 converts the charge, which is obtained by photoelectric conversion by the photoelectric conversion unit 21 and transferred from the photoelectric conversion unit 21 by the transfer transistor 22, into a voltage.

The reset transistor 24 has a gate electrode connected to the control line RSTL and a source electrode connected to the charge-voltage conversion unit 23. A power supply voltage V_{DD} is supplied to a drain electrode of the reset transistor 24. The reset transistor 24 resets the charge accumulated in the charge-voltage conversion unit 23 in accordance with a control signal given from the drive unit 12 through the control line RSTL.

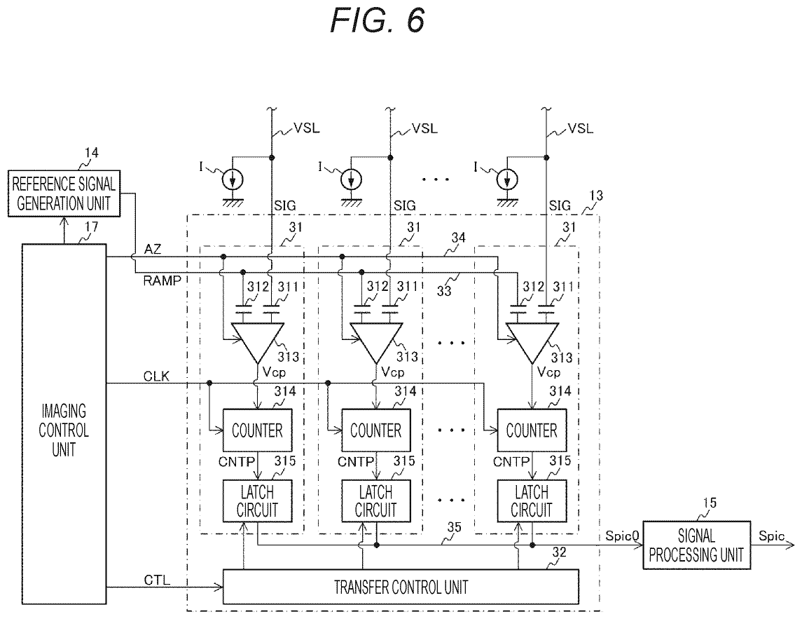

The amplification transistor 25 has a gate electrode connected to the charge-voltage conversion unit 23 and a source electrode connected to a drain electrode of the selection transistor 26. The power supply voltage V_{DD} is supplied to a drain electrode of the amplification transistor 25. The amplification transistor 25 serves as an input unit of a circuit that reads out electric charges obtained by photoelectric conversion in the photoelectric conversion unit 21, that is, a source follower circuit. That is, the amplification transistor 25 has the source electrode connected to the signal line VSL via the selection transistor 26, thereby forming a source follower circuit with a constant current source I (see FIG. 6), which will be described later, connected to one end of the signal line VSL.

The selection transistor 26 has a gate electrode connected to the control line SELL, has a drain electrode connected to the source electrode of the amplification transistor 25, and has a source electrode connected to the signal line VSL. Furthermore, the selection transistor 26 selects any pixel 20 in the pixel array unit 11 under selective scanning by the drive unit 12.

In the circuit configuration described above, in the pixel 20, when the transfer transistor 22 and the reset transistor 24 are turned on, the charge accumulated in the photoelectric conversion unit 21 is discharged. Meanwhile, when the transfer transistor 22 and the reset transistor 24 are turned off, an exposure period is started, photoelectric conversion is performed in the photoelectric conversion unit 21, and a charge of an amount corresponding to an amount of received light is accumulated.

After the exposure period ends, the pixel 20 outputs the signal SIG including a reset voltage Vreset and the pixel voltage Vpix to the signal line VSL. Specifically, first, when the selection transistor 26 is turned on, the pixel 20 is electrically connected to the signal line VSL. As a result, the amplification transistor 25 is electrically connected to the constant current source I (see FIG. 6), which will be described later, connected to one end of the signal line VSL in an input unit of the readout unit 13, and operates as a source follower.

Then, as described later, when the reset transistor 24 is turned on, the voltage of the charge-voltage conversion unit 23 is reset, and in a subsequent pre-charge phase (P-phase) period, the pixel 20 outputs a voltage of the charge-voltage conversion unit 23 at that time as a reset voltage Vreset. Furthermore, when the transfer transistor 22 is turned on, a charge is transferred from the photoelectric conversion unit 21 to the charge-voltage conversion unit 23, and in a subsequent data phase (D-phase) period, the pixel 20 outputs a voltage of the charge-voltage conversion unit 23 at that time as the pixel voltage Vpix. A difference voltage between the pixel voltage Vpix and the reset voltage Vreset corresponds to an amount of received light of the pixel 20 in the exposure period. In this way, the pixel 20 outputs the signal SIG including the reset voltage Vreset and the pixel voltage Vpix to the signal line VSL.

The red (R) pixel block 100R illustrated in FIG. 5 includes eight photoelectric conversion units 21 and eight transfer transistors 22. The pixel block 100R further includes one charge-voltage conversion unit 23, one reset transistor 24, one amplification transistor 25, and one selection transistor 26.

Here, for example, an N-type MOS field-effect transistor can be used as the transfer transistors 22, the reset transistor 24, the amplification transistor 25, and the selection transistor 26. However, a combination of conductivity types of the transfer transistors 22, the reset transistor 24, the amplification transistor 25, and the selection transistor 26 exemplified here is only an example, and the combination is not limited to these.

The eight photoelectric conversion units 21 and the eight transfer transistors 22 correspond to the eight pixels 20R included in the pixel block 100R, respectively. Furthermore, the pixel block 100R has a pixel circuit configuration in which the charge-voltage conversion unit 23, the reset transistor 24, the amplification transistor 25, and the selection transistor 26 are shared among the ten pixels 20R. Gate electrodes of the eight transfer transistors 22 are connected to different control lines TRGL among the eight control lines TRGL (in this example, control lines TRGL1, TRGL 2, and TRGL5 to TRGL 10).

Furthermore, the pixel block 100Gb includes ten photoelectric conversion units 21 and ten transfer transistors 22 (not illustrated) similarly to the pixel block 100Gr illustrated in FIG. 4. The ten photoelectric conversion units 21 and the ten transfer transistors 22 correspond to the ten pixels 20Gb included in the pixel block 100Gb, respectively. Gate electrodes of the transfer transistors 22 are connected to different control lines TRGL among the ten control lines TRGL.

The pixel block 100Gb further includes one charge-voltage conversion unit 23, one reset transistor 24, one amplification transistor 25, and one selection transistor 26. Furthermore, the pixel block 100Gb has a pixel circuit configuration in which the charge-voltage conversion unit 23, the reset transistor 24, the amplification transistor 25, and the selection transistor 26 are shared among the ten pixels 20Gb.

Furthermore, the pixel block 100B includes eight photoelectric conversion units 21 and eight transfer transistors 22 similarly to the pixel block 100R illustrated in FIG. 5. The eight photoelectric conversion units 21 and the eight transfer transistors 22 correspond to the eight pixels 20B included in the pixel block 100B, respectively. Gate electrodes of the transfer transistors 22 are connected to different control lines TRGL among the eight control lines TRGL.

The pixel block 100B further includes one charge-voltage conversion unit 23, one reset transistor 24, one amplification transistor 25, and one selection transistor 26. Furthermore, the pixel block 100B has a pixel circuit configuration in which the charge-voltage conversion unit 23, the reset transistor 24, the amplification transistor 25, and the selection transistor 26 are shared among the eight pixels 20B.

### [Configuration Example of Readout Unit]

Next, a configuration example of the readout unit 13 will be described. FIG. 6 is a block diagram illustrating a configuration example of the readout unit 13 of the imaging element 1 in the first embodiment. Note that FIG. 6 also illustrates the reference signal generation unit 14, the signal processing unit 15, and the imaging control unit 17 in addition to the readout unit 13.

The signal SIG including the pixel voltage Vpix, which is read from each pixel 20 of the pixel array unit 11 via the plurality of signal lines VSL, is input to the readout unit 13. Note that the constant current source I is connected to each of the plurality of signal lines VSL in the input unit of the readout unit 13. The constant current source I has one end connected to a corresponding one of the signal lines VSL and the other end that is grounded, and has a function of causing a predetermined current to flow through the corresponding one of the signal lines VSL.

The readout unit 13 includes a plurality of analog-digital conversion units 31 and a transfer control unit 32. Each of the plurality of analog-digital conversion units 31 is provided for a corresponding one of the plurality of signal lines VSL, and performs analog-digital conversion on the signal SIG in the corresponding signal line VSL. Hereinafter, the analog-digital conversion unit 31 corresponding to a certain signal line VSL will be described.

The analog-digital conversion unit 31 includes capacitive elements 311 and 312, a comparison circuit 313, a counter 314, and a latch circuit 315.

One end of the capacitive element 311 is connected to the signal line VSL, and the other end of the capacitive element 311 is connected to one input end of the comparison circuit 313. The signal SIG including the pixel voltage Vpix is supplied from each pixel 20 of the pixel array unit 11 to the capacitive element 311 through the signal line VSL.

One end of the capacitive element 312 is connected to a signal line 33 that transmits the reference signal RAMP, and the other end of the capacitive element 312 is connected to the other input end of the comparison circuit 313. To the capacitive element 312, the reference signal RAMP is supplied from the reference signal generation unit 14 through the signal line 33.

The comparison circuit 313 compares the signal SIG supplied from each pixel 20 of the pixel array unit 11 via the signal line VSL and the capacitive element 311 with the reference signal RAMP supplied from the reference signal generation unit 13 via the signal line 33 and the capacitive element 312, and outputs a signal Vcp as a comparison result.

The comparison circuit 313 sets an operating point by setting voltages of the capacitive elements 311 and 312 on the basis of a control signal AZ supplied from the imaging control unit 17 through a signal line 34. Then, after setting the operating point, the comparison circuit 313 performs a comparison operation of comparing the reset voltage Vreset included in the signal SIG with the voltage of the reference signal RAMP in the P-phase period. Furthermore, in the D-phase period, the comparison circuit 313 performs a comparison operation of comparing the pixel voltage Vpix included in the signal SIG with the voltage of the reference signal RAMP.

The counter 314 is configured to perform a counting operation of counting pulses of a clock signal CLK supplied from the imaging control unit 17 on the basis of the signal Vcp supplied from the comparison circuit 313. Specifically, in the P-phase period, the counter 314 generates a count value CNTP by counting pulses of the clock signal CLK until the signal Vcp output from the comparison circuit 313 transitions, and outputs the count value CNTP as a digital code having a plurality of bits. Furthermore, in the D-phase period, the counter 314 generates a count value CNTD by counting pulses of the clock signal CLK until the signal Vcp output from the comparison circuit 313 transitions, and outputs the count value CNTD as a digital code having a plurality of bits.

The latch circuit 315 temporarily holds the digital code supplied from the counter 314 and outputs the digital code to a bus wiring 35 on the basis of an instruction from the transfer control unit 32.

The transfer control unit 32 controls the latch circuits 315 of the plurality of analog-digital conversion units 31 to sequentially output the digital codes to the bus wiring 35 on the basis of a control signal CTL supplied from the imaging control unit 17. By using the bus wiring 35, the readout unit 13 sequentially transfers the plurality of digital codes output from the plurality of analog-digital conversion units 31 to the signal processing unit 15 as the image signal Spic0.

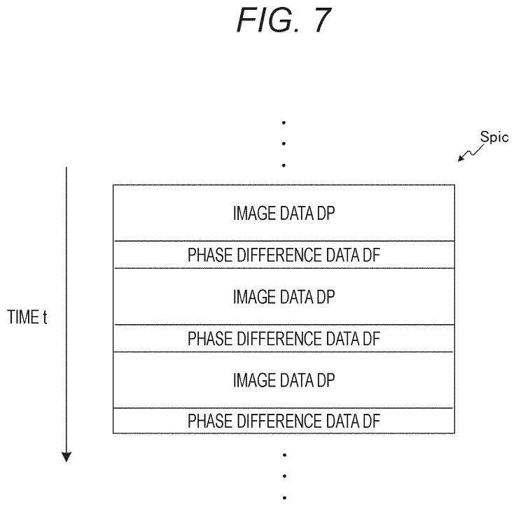

Under the control of the imaging control unit 17, the signal processing unit 15 performs predetermined signal processing on the image signal Spic0 supplied from the readout unit 13 and outputs the image signal Spic thus obtained including the image data DP and the phase difference data DF. Specifically, as illustrated in FIG. 7, the signal processing unit 15 generates and outputs the image signal Spic by alternately arranging the phase difference data DF related to the pixels 20 of a plurality of rows.

### [Semiconductor Chip Structure]

As the semiconductor chip structure of the imaging element 1 having the above configuration, a so-called flat-type semiconductor chip structure and a so-called stacked-type semiconductor chip structure can be illustrated as an example. Furthermore, regarding the pixel structure, when the substrate surface on the side on which a wiring layer is formed is defined as a front surface (front), a back-illuminated pixel structure which receives light emitted from the back surface side opposite to the front surface can be employed, or a front-illuminated pixel structure which receives light emitted from the front surface side can be employed.

The flat-type semiconductor chip structure and the stacked-type semiconductor chip structure will be schematically described below.

### (Flat-Type Semiconductor Chip Structure)

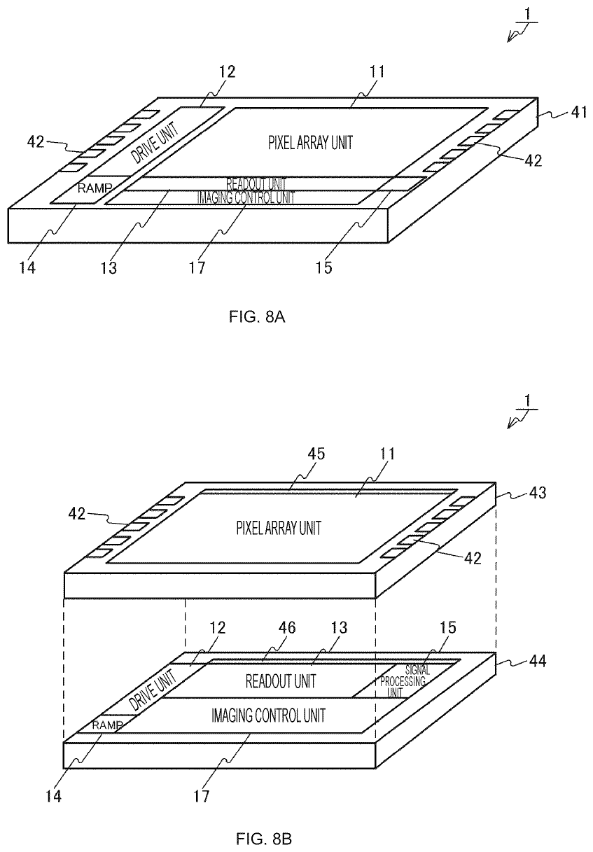

a of FIG. 8 is a perspective view schematically illustrating a flat-type chip structure of the imaging element 1. The flat-type semiconductor chip structure is a structure in which constituent elements of a peripheral circuit unit of the pixel array unit 11 are formed on the same semiconductor substrate (semiconductor chip) 41 as that of the pixel array unit 11 in which the pixels 20 are arranged in a matrix. Specifically, the drive unit 12, the readout unit 13, the reference signal generation unit 14, the signal processing unit 15, the imaging control unit 17, and the like are formed on the same semiconductor substrate 41 as the pixel array unit 11. Pads 42 for external connection and power supply are provided, for example, at both left and right ends of the semiconductor substrate 41.

### (Stacked-Type Semiconductor Chip Structure)

b of FIG. 8 is an exploded perspective view schematically illustrating a stacked-type semiconductor chip structure of the imaging element 1. The stacked-type semiconductor chip structure is a structure in which at least two semiconductor substrates of a first-layer semiconductor substrate 43 and a second-layer semiconductor substrate 44 are stacked.

In the stacked-type semiconductor chip structure, the first-layer semiconductor substrate 43 is a pixel chip on which the pixel array unit 11 in which the pixels 20 are two-dimensionally arranged in a matrix is provided. Pads 42 for external connection and power supply are provided, for example, at both left and right ends of the first-layer semiconductor substrate 43.

The second-layer semiconductor substrate 44 is a circuit chip on which the peripheral circuit unit of the pixel array unit 11, that is, the drive unit 12, the readout unit 13, the reference signal generation unit 14, the signal processing unit 15, the imaging control unit 17, and the like are formed. Note that the arrangement of the drive unit 12, the readout unit 13, the reference signal generation unit 14, the signal processing unit 15, the imaging control unit 17, and the like is an example, and is not limited to this arrangement example.

The pixel array unit 11 on the first-layer semiconductor substrate 43 and the peripheral circuit unit on the second-layer semiconductor substrate 44 are electrically connected via joints 45 and 46 including a metal-metal junction including a Cu—Cu junction, a through silicon via (TSV), a microbump, and the like.

According to the stacked-type semiconductor chip structure described above, a process suitable for manufacturing the pixel array unit 11 can be applied to the first-layer semiconductor substrate 43, and a process suitable for manufacturing the circuit portion can be applied to the second-layer semiconductor substrate 44. Thus, the process can be optimized during manufacture of the imaging element 1. In particular, in manufacturing the circuit portion, there is an advantage that an advanced process can be applied and a circuit scale can be expanded.

### [Regarding Pixel Block and Pixel Pair]

As described above, in the imaging element 1 according to the first embodiment, the plurality of pixel blocks 100 each having the plurality of pixels 20 including color filters of the same color is provided. The plurality of pixels 20 in the pixel block 100 is divided into the plurality of pixel pairs 90 each including two pixels 20. Furthermore, the plurality of lenses 101 is provided at positions corresponding to the plurality of pixel pairs 90.

With the above configuration, in the imaging element 1 according to the first embodiment, the phase difference data DF can be generated with high resolution throughout the entire surface of the pixel array unit 11. Therefore, in an electronic apparatus having an imaging function such as a digital still camera in which such an imaging element 1 is mounted, high-accuracy autofocus can be realized. As a result, image quality can be improved in the imaging element 1, and therefore a captured image that is easier to view can be obtained.

Furthermore, in the imaging element 1, the number of pixels in one certain pixel block 100 is set to be larger than the number of pixels in another certain pixel block 100. Specifically, in the example of the first embodiment, the number of pixels 20Gr in the pixel block 100Gr and the number of pixels 20Gb in the pixel block 100Gb are set to be larger than the number of pixels 20R in the pixel block 100R and the number of pixels 20B in the pixel block 100B. As a result, for example, light reception sensitivity of green that is larger in the number of pixels can be enhanced, and therefore image quality of a captured image can be enhanced, and a captured image that is easier to view can be obtained.

Furthermore, according to the imaging element 1 according to the first embodiment, even if a pixel size is reduced along with improvement in image quality of a captured image, it is possible to contribute to realization of high-accuracy autofocus in an electronic apparatus having an imaging function such as a digital still camera while maintaining a basic configuration of a phase difference detection pixel, that is, the two pixels 20 of the pixel pair 90.

### [Regarding Drive Mode of Imaging Element]

The imaging element 1 according to the first embodiment has a pixel circuit configuration in which the charge-voltage conversion unit 23 and succeeding pixel constituent elements, that is, the reset transistor 24, the amplification transistor 25, and the selection transistor 26 are shared among the plurality of pixels 20 (see FIGS. 4 and 5). In the imaging element 1 having the pixel-sharing pixel circuit, for example, three drive modes, specifically, a first drive mode, a second drive mode, and a third drive mode can be set as a drive mode.

The first mode is an all-pixel readout mode in which readout is individually performed without performing addition (pixel addition) among the plurality of pixels 20 that shares the charge-voltage conversion unit 23 and succeeding pixel constituent elements. The second drive mode is an autofocus (AF) mode in which addition is performed between the two pixels 20 of the pixel pair 90 to generate the phase difference data DE. The third drive mode is an all-pixel addition mode in which readout is performed by performing addition (pixel addition) among all the pixels 20 that share the charge-voltage conversion unit 23 and succeeding pixel constituent elements.

### [Regarding Difference in Output Signal Amount Among Colors]

By the way, in the imaging element 1 having the pixel circuit configuration in which the charge-voltage conversion unit 23 and succeeding pixel constituent elements are shared, a difference in the number of pixels that share the charge-voltage conversion unit 23 and succeeding pixel constituent elements as in the cases of FIGS. 4 and 5 means a difference in the number of transfer transistors 22 electrically connected to the charge-voltage conversion unit 23. As a result, conversion efficiency of the charge-voltage conversion unit 23 and an amount of charge handled in the all-pixel addition mode varies from one charge-voltage conversion unit 23 to another, and therefore a difference occurs in output signal amount among colors after analog-digital conversion performed by the analog-digital conversion unit 31, and an output signal amount proportional to an exposure time cannot be obtained.

The conversion efficiency n of the charge-voltage conversion unit 23 is given by η=1/C. Here, C is capacitance of the charge-voltage conversion unit 23 including the capacitance C_{FD} of the floating diffusion region (FD region). In the case of the green (Gr, Gb) pixel blocks 100Gr and 100Gb, the number of pixels sharing the charge-voltage conversion unit 23 and succeeding pixel constituent elements is larger than that of the red (R) pixel block 100R and the blue (B) pixel block 100R, and the number of transfer transistors 22 electrically connected to the charge-voltage conversion unit 23 is larger accordingly.

In a case where the number of transfer transistors 22 electrically connected to the charge-voltage conversion unit 23 is large, the capacitance C of the charge-voltage conversion unit 23 is large, and therefore the conversion efficiency of the pixel block 100Gr/Gb having a relatively large number of pixels is smaller than the conversion efficiency of the pixel block 100R/B having a relatively small number of pixels. Furthermore, there is a difference in wiring layout (routing) between the pixel block 100Gr/Gb and the pixel block 100R/B, and therefore a difference occurs in conversion efficiency due to the difference. Furthermore, in a drive mode in which the number of pixels to be added varies, the number of electrons handled by the charge-voltage conversion unit 23 varies from one color to another.

### [Regarding Digital Gain Correction]

In the imaging element 1 according to the first embodiment, control of absorbing a difference in output signal amount among colors is performed for the purpose of obtaining an output signal amount proportional to an exposure time in each of the drive modes, specifically, the all-pixel readout mode, the AF mode, and the all-pixel addition mode. More specifically, in the first embodiment, the control of absorbing a difference in output signal amount among colors is performed by digital gain correction processing in a digital region after analog-digital conversion performed by the analog-digital conversion unit 31. Hereinafter, a specific example of the digital gain correction processing for absorbing a difference in output signal amount among colors will be described.

In performing the correction processing for absorbing a difference in output signal amount among colors, that is, the digital gain correction processing, it is necessary to acquire an output signal amount for each color. The acquisition of the output signal amount for each color is performed by using an external measurement apparatus (not illustrated) in an adjustment stage before shipment of the imaging element 1. Specifically, the output signal amount for each color is acquired on the basis of the number of pixels to be added in each drive mode and conversion efficiency used by the charge-voltage conversion unit 23. Information on the output signal amount for each color thus acquired in advance is stored in the memory unit 16 illustrated in FIG. 1 before shipment.

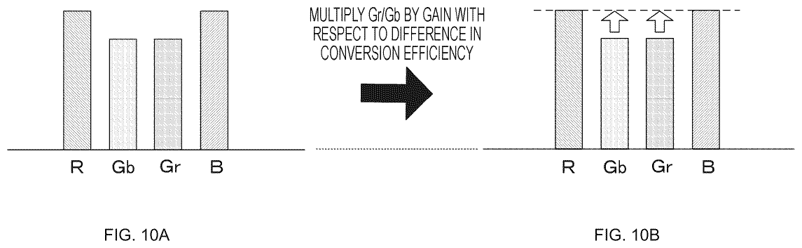

Here, the difference in output signal amount among colors will be described. As described above, the conversion efficiency of the pixel block 100Gr/Gb having a relatively large number of pixels is smaller than the conversion efficiency of the pixel block 100R/B having a relatively small number of pixels. Therefore, in the case of the all-pixel readout mode in which readout is individually performed without performing pixel addition and the AF mode in which addition is performed between the two pixels 20 of the pixel pair 90, R and B output signal amounts are larger than G (Gr and Gb) output signal amounts, and there is a difference in output signal amount, as illustrated in a of FIG. 10.

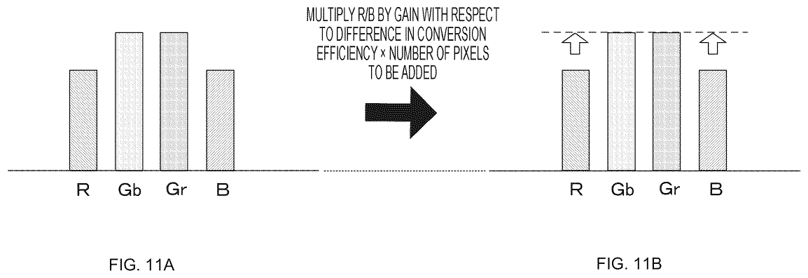

On the other hand, in the case of the all-pixel addition mode in which addition is performed among all the pixels 20, the number of electrons handled by the charge-voltage conversion unit 23 by all-pixel addition is larger in the pixel block 100Gr/Gb in which the number of pixels to be added is relatively large. Therefore, as illustrated in a of FIG. 11, the G (Gr and Gb) output signal amounts are larger than the R and B output signal amounts, and there is a difference in output signal amount.

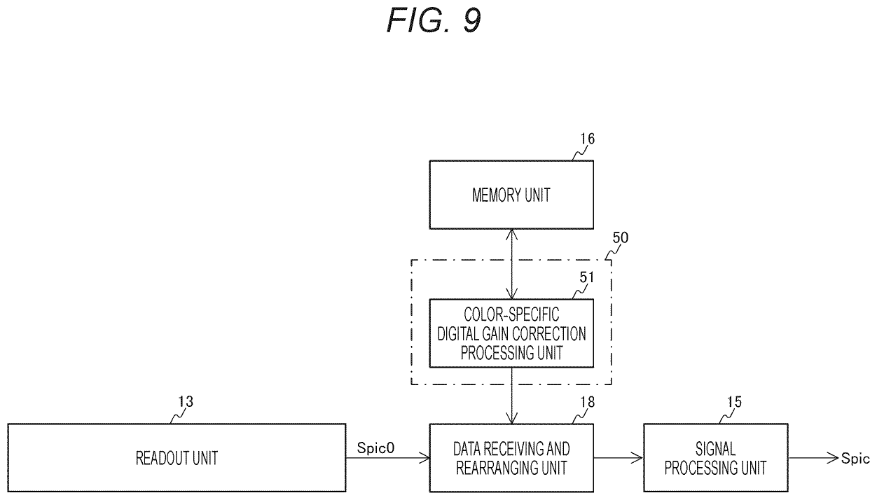

FIG. 9 is a block diagram illustrating a configuration example of a signal amount adjustment unit 50 of the imaging element 1 in the first embodiment. Note that FIG. 9 also illustrates the readout unit 13, the signal processing unit 15, and the memory unit 16 in addition to the signal amount adjustment unit 50.

Typically, a data receiving and rearranging unit 18 is provided in a stage preceding the signal processing unit 15 although illustration thereof is omitted in FIGS. 1 and 6. The data receiving and rearranging unit 18 receives analog-digital converted pixel data sequentially output from the signal processing unit 15, and performs processing of rearranging the pixel data into pixel arrangement corresponding to the RGB Bayer arrangement of the pixel block 100R, the pixel block 100Gr, the pixel block 100Gb, and the pixel block 100B.

The signal amount adjustment unit 50 includes a color-specific digital gain correction processing unit 51, and performs correction processing for absorbing a difference in output signal amount among colors on the basis of the information on the output signal amount for each color acquired in advance before shipment and stored in the memory unit 16 under the correction processing performed by the color-specific digital gain correction processing unit 51. Specifically, the color-specific digital gain correction processing unit 51 performs gain adjustment of absorbing the difference in output signal amount among the colors by adjusting a signal amount of a pixel of a predetermined color, for example, after rearranging processing performed by the data receiving and rearranging unit 18 by a gain that can achieve matching of output signal amounts of the colors. Here, “matching” includes not only strict matching but also substantial matching, and existence of various variations caused by design or manufacturing is allowed.

Hereinafter, the color-specific digital gain correction processing for absorbing a difference in output signal amount among colors will be described more specifically.

(Case of all-Pixel Readout Mode/AF Mode)

As illustrated in a of FIG. 10, in the case of the all-pixel readout mode in which signals of the pixels 20 of the pixel block 100 (100R, 100Gr, Gb, 100B) are individually read and the case of the AF mode in which signals of the two pixels 20 of the pixel pair 90 are added and the added signals are read, R and B output signal amounts are larger than G (Gr and Gb) output signal amounts. As described above, such a difference in output signal amount among colors occurs because of a difference in conversion efficiency of the charge-voltage conversion unit 23 among colors. The information on the difference in output signal amount is acquired in advance and stored in the memory unit 16.

In the case of the all-pixel readout mode/AF mode, the color-specific digital gain correction processing unit 51 of the signal amount adjustment unit 50 adjusts the output signal amounts by digital gain correction so that the relatively small G (Gr and Gb) output signal amounts are increased to match the relatively large R and B output signal amounts as illustrated in b of FIG. 10 on the basis of the information on the difference in output signal amount stored in the memory unit 16, for example, at an initial stage of startup of the imaging element 1. That is, in this digital gain correction, correction of multiplying G (Gr and Gb) output signal amounts by a gain is performed with respect to the difference in conversion efficiency.

By adjusting the output signal amounts by the color-specific digital gain correction processing, the difference between the R and B output signal amounts and the G (Gr and Gb) output signal amounts in the case of the all-pixel readout mode and the AF mode can be absorbed, so that the R and B output signal amounts and the G (Gr and Gb) output signal amounts match. As a result, an output signal amount proportional to an exposure time can be obtained for each pixel 20 of the pixel block 100 (100R, 100Gr, Gb, 100B), a captured image that is easier to view can be obtained.

(Case of all-Pixel Addition Mode)

As illustrated in a of FIG. 11, in the case of the all-pixel addition mode in which the signals of all the pixels 20 of the pixel block 100 (100R, 100Gr, Gb, 100B) are added and the added signals are read, the G (Gr and Gb) output signal amounts are larger than the R and B output signal amounts. Such a difference in output signal amount among colors occurs mainly because the number of electrons handled by the charge-voltage conversion unit 23 increases by the all-pixel addition. The information on the difference in output signal amount is acquired in advance and stored in the memory unit 16.

In the case of the all-pixel addition mode, the color-specific digital gain correction processing unit 51 of the signal amount adjustment unit 50 adjusts the output signal amounts by digital gain correction so that the relatively small R and B output signal amounts are increased to match the relatively large G (Gr and Gb) output signal amounts as illustrated in b of FIG. 11 on the basis of the information on the difference in output signal amount stored in the memory unit 16, for example, at an initial stage of startup of the imaging element 1. That is, in this digital gain correction, correction of multiplying the R and B output signal amounts by a predetermined gain is performed with respect to a difference in conversion efficiency×the number of pixels to be added.

By adjusting the output signal amounts by the color-specific digital gain correction processing, the difference between the R and B output signal amounts and the G (Gr and Gb) output signal amounts in the case of the all-pixel addition mode can be absorbed, so that the R and B output signal amounts and the G (Gr and Gb) output signal amounts match. As a result, an output signal amount proportional to an exposure time can be obtained for each pixel 20 of the pixel block 100 (100R, 100Gr, Gb, 100B), a captured image that is easier to view can be obtained.

### 2. Second Embodiment

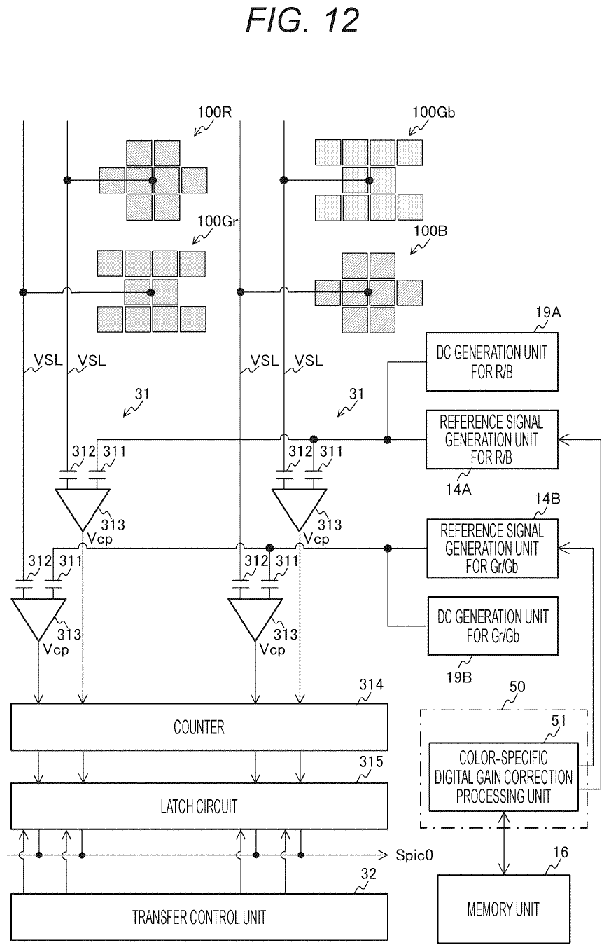

FIG. 12 is a circuit diagram illustrating a configuration example of a digital-analog conversion unit in the second embodiment of the present technology. The second embodiment is an example in which control of absorbing a difference in output signal amount among colors is performed by analog gain correction. Note that an overall configuration of an imaging element 1 is similar to that of the first embodiment described above, and thus detailed description is omitted.

In the first embodiment described above, one reference signal generation unit 14 that generates the reference signal RAMP used as a signal for reference for a signal of each pixel 20 of the pixel block 100 (100R, 100Gr, Gb, 100B) in the analog-digital conversion in the single-slope analog-digital conversion unit 31 is provided common to the colors. That is, in the first embodiment, a slope of the reference signal RAMP is common to pixel signals of the respective colors, and the analog-digital conversion unit 31 performs the color-specific digital gain correction processing in the digital region after the analog-digital conversion.

On the other hand, in the second embodiment, a plurality of reference signal generation units 14, in this example, two reference signal generation units, specifically, a reference signal generation unit 14A for R/B and a reference signal generation unit 14B for Gr/Gb are provided. The reference signal generation unit 14A for R/B is a reference signal generation unit for adjusting output signal amounts concerning colors R/B output from a pixel block 100R and a pixel block 100B by an analog gain determined by a slope of a reference signal RAMP of a generated ramp wave. The reference signal generation unit 14B for Gr/Gb is a reference signal generation unit for adjusting output signal amounts concerning colors Gr/Gb output from a pixel block 100Gr and a pixel block 100Gb by an analog gain determined by a slope of a reference signal RAMP of a generated ramp wave.

In FIG. 12, a DC generation unit 19A for R/B and a DC generation unit 19B for Gr/Gb are also illustrated in addition to a signal amount adjustment unit 50 and a memory unit 16. The DC generation unit 19A for R/B generates a direct current (DC) voltage to be applied to the reference signal RAMP of the ramp wave output from the reference signal generation unit 14A for R/B. The DC generation unit 19B for Gr/Gb generates a DC voltage to be applied to the reference signal RAMP of the ramp wave output from the reference signal generation unit 14B for Gr/Gb.

The signal amount adjustment unit 50 includes a color-specific digital gain correction processing unit 51, and performs correction processing for absorbing a difference in output signal amount among colors on the basis of the information on the output signal amount for each color acquired in advance before shipment and stored in the memory unit 16 under the correction processing performed by the color-specific digital gain correction processing unit 51. Specifically, the color-specific digital gain correction processing unit 51 performs gain adjustment of absorbing a difference in output signal amount among colors by controlling an analog gain determined by the slope of the reference signal RAMP of the ramp wave generated by the reference signal generation unit 14A for R/B and the slope of the reference signal RAMP of the ramp wave generated by the reference signal generation unit 14B for Gr/Gb.

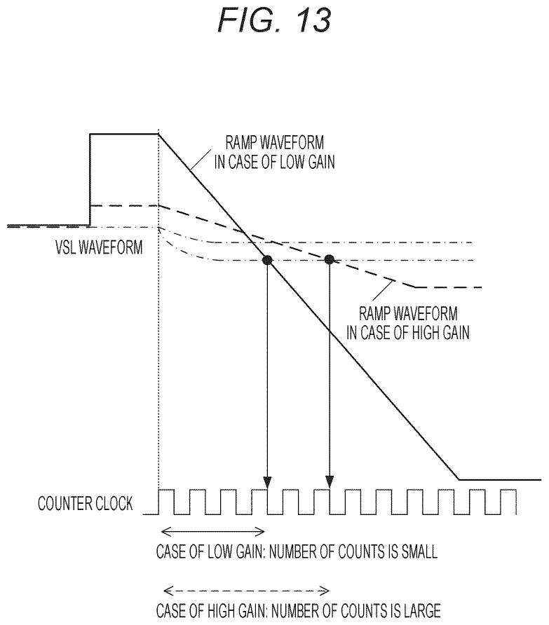

FIG. 13 is a waveform diagram illustrating a timing relationship among a waveform (RAMP waveform) of the reference signal RAMP in the case of high gain, a waveform of the reference signal RAMP of low gain, a waveform (VSL waveform) of a signal line VSL, and a clock (counter clock) of a counter 314. In the waveform diagram of FIG. 13, the slope of the RAMP waveform in the case of low gain is steep as indicated by the solid line (that is, a voltage level of 1 LSB is large), and the slope of the RAMP waveform in the case of high gain is gentle as indicated by the broken line (that is, a voltage level of 1 LSB is small). Furthermore, the number of counts of the counter 314 is relatively small in the case of low gain, and the number of counts of the counter 314 is relatively large in the case of high gain, and thus, an output increases (that is, gain is applied).

The concept of the color-specific digital gain correction processing for absorbing a difference in output signal amount among colors performed by the color-specific digital gain correction processing unit 51 of the signal amount adjustment unit 50 is basically the same as that in the first embodiment.

(Case of all-Pixel Readout Mode/AF Mode)

As illustrated in a of FIG. 10, in the case of the all-pixel readout mode and the AF mode, R and B output signal amounts are larger than G (Gr and Gb) output signal amounts. In this case, for example, the color-specific digital gain correction processing unit 51 of the signal amount adjustment unit 50 sets a low gain for the relatively large R and B output signal amounts and sets a high gain for the relatively small G (Gr and Gb) output signal amounts on the basis of the information on the difference in output signal amount stored in the memory unit 16 at an initial stage of startup of the imaging element 1.

The low gain and the high gain set here are analog gains determined by the slope of the reference signal RAMP of the ramp wave generated by the reference signal generation unit 13A for R/B and the slope of the reference signal RAMP of the ramp wave generated by the reference signal generation unit 13B for Gr/Gb. By this gain adjustment, the relatively small G (Gr and Gb) output signal amounts can be increased to match the relatively large R and B output signal amounts, as illustrated in b of FIG. 10. As a result, an output signal amount proportional to an exposure time can be obtained for each pixel 20 of the pixel block 100 (100R, 100Gr, Gb, 100B), a captured image that is easier to view can be obtained.

(Case of all-Pixel Addition Mode)

As illustrated in a of FIG. 11, in the case of the all-pixel addition mode in which the signals of all the pixels 20 of the pixel block 100 (100R, 100Gr, Gb, 100B) are added and the added signals are read, the G (Gr and Gb) output signal amounts are larger than the R and B output signal amounts. In this case, the color-specific digital gain correction processing unit 51 of the signal amount adjustment unit 50 sets a low gain for the relatively large G (Gr and Gb) output signal amounts and sets a high gain for the relatively small R and B output signal amounts on the basis of the information on the difference in output signal amount stored in the memory unit 16 at an initial stage of startup of the imaging element 1.

By this gain adjustment, the relatively small R and B output signal amounts can be increased to match the relatively large G (Gr and Gb) output signal amounts, as illustrated in b of FIG. 11. As a result, an output signal amount proportional to an exposure time can be obtained for each pixel 20 of the pixel block 100 (100R, 100Gr, Gb, 100B), a captured image that is easier to view can be obtained.

### 3. Modifications

Note that the embodiments described above show examples for embodying the present technology, and the matters in the embodiments and the matters specifying the invention in the claims have corresponding relationships, respectively. Similarly, the matters specifying the invention in the claims and matters with the same names in the embodiments of the present technology have correspondence relationships, respectively. However, the present technology is not limited to the embodiments, and can be embodied by applying various modifications to the embodiments without departing from the gist of the present technology.

### 4. Example of Application to Electronic Apparatus

The imaging element according to the embodiments of the present technology described above is applicable to various electronic apparatuses having an imaging function such as an imaging device such as a digital still camera or a video camera, a mobile terminal device having an imaging function such as a mobile phone, and a copier using an imaging device in an image reading unit.

### (Example of Imaging Device)

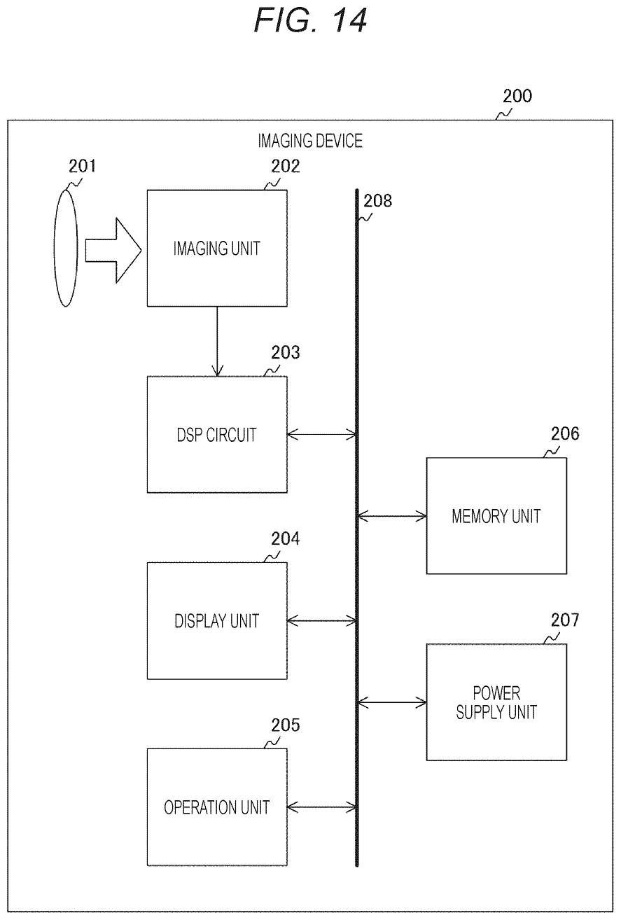

FIG. 14 is a block diagram illustrating a configuration example of an imaging device which is an example of an electronic apparatus to which the present technology is applied.

An imaging element 200 according to the present application example is a device for imaging a subject, and includes an imaging optical system 201 including a lens group and the like, an imaging unit 202, a digital signal processor (DSP) circuit 203, a display unit 204, an operation unit 205, a memory unit 206, and a power supply unit 207. These are connected to one another by a bus wiring 208. As the imaging element 200, for example, in addition to a digital camera such as a digital still camera, a smartphone and a personal computer having an imaging function, an in-vehicle camera, and the like are assumed.

The imaging unit 202 generates pixel data by photoelectric conversion. As the imaging unit 202, the imaging element according to the above embodiment is used. Light from a subject is condensed and guided to a light receiving surface of the imaging unit 202 by the imaging optical system 201 arranged on an incident light side. The imaging unit 202 supplies pixel data generated by photoelectric conversion to the DSP circuit 203 in the subsequent stage.

The DSP circuit 203 executes predetermined signal processing on the pixel data from the imaging unit 202. The display unit 204 displays the pixel data. As the display unit 204, for example, a liquid crystal panel or an organic electro luminescence (EL) panel is assumed. The operation unit 205 generates an operation signal according to a user's operation. The memory unit 206 stores various types of data such as the pixel data. The power supply unit 207 supplies power to the imaging unit 202, the DSP circuit 203, the display unit 204, and the like.

### 5. Example of Application of Embodiments of Present Technology

The above embodiments of the present technology can be applied to various technologies as exemplified below.

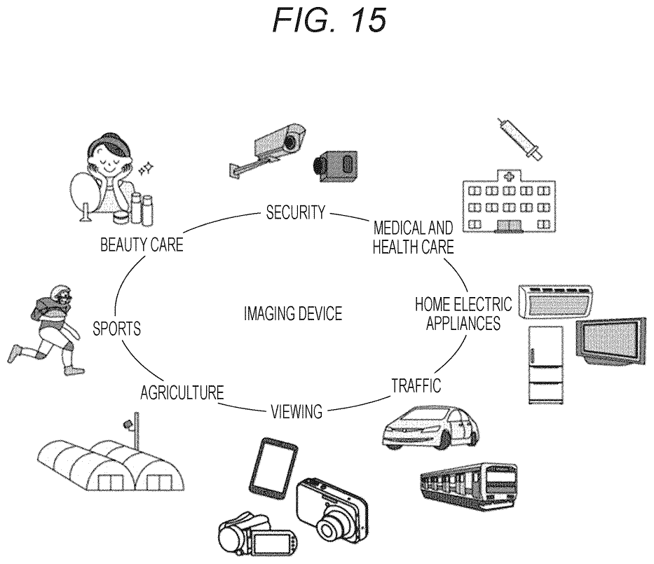

FIG. 15 illustrates an example of fields to which the embodiments of the present technology are applied.

The imaging device according to the embodiments of the present technology can be, for example, used as a device that captures an image to be used for viewing, such as a digital camera or a portable device having a camera function.

Furthermore, this imaging device can be used as a device for traffic purpose such as an in-vehicle sensor which takes an image of surroundings, interior, or the like of an automobile, a surveillance camera for monitoring traveling vehicles and roads, and a ranging sensor which measures a distance between vehicles and the like for safe driving such as automatic stop, recognition of a driver's condition and the like.

Furthermore, this imaging device can be used as a device used for home electric appliances such as a television, a refrigerator, and an air conditioner in order to capture an image of a gesture of a user and perform device operation according to the gesture.

Furthermore, this imaging device can be used as a device for medical and health care use such as an endoscope and a device that performs angiography by receiving infrared light.

Furthermore, this imaging device can be used as a device for security use such as a security monitoring camera and an individual authentication camera.

Furthermore, this imaging device can be used as a device used for beauty care, such as a skin measuring instrument for imaging skin, and a microscope for imaging the scalp.

Furthermore, this imaging device can be used as a device used for sport, such as an action camera or a wearable camera for sports applications or the like.

Furthermore, this imaging device can be used as a device used for agriculture, such as a camera for monitoring a condition of a field or crop.

### 6. Example of Application to Mobile Body

The technology according to the present disclosure (the present technology) can be applied to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

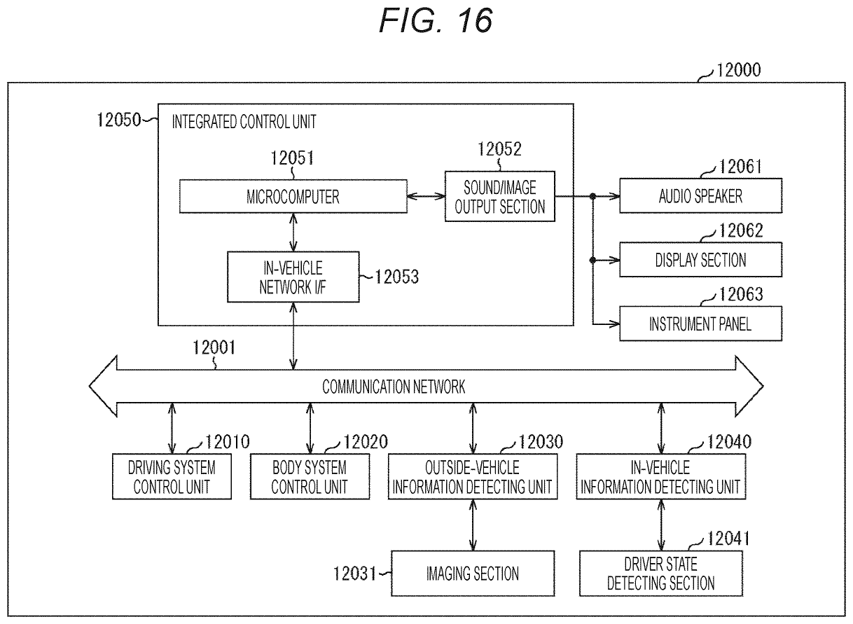

FIG. 16 is a block diagram illustrating a schematic configuration example of a vehicle control system as an example of a mobile body control system to which the technology according to the present disclosure can be applied.

The vehicle control system 12000 includes a plurality of electronic control units connected to each other via a communication network 12001. In the example illustrated in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and an in-vehicle network interface (I/F) 12053 are illustrated as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 16, an audio speaker 12061, a display section 12062, and an instrument panel 12063 are exemplified as the output devices. The display section 12062 may, for example, include at least one of an on-board display and a head-up display.

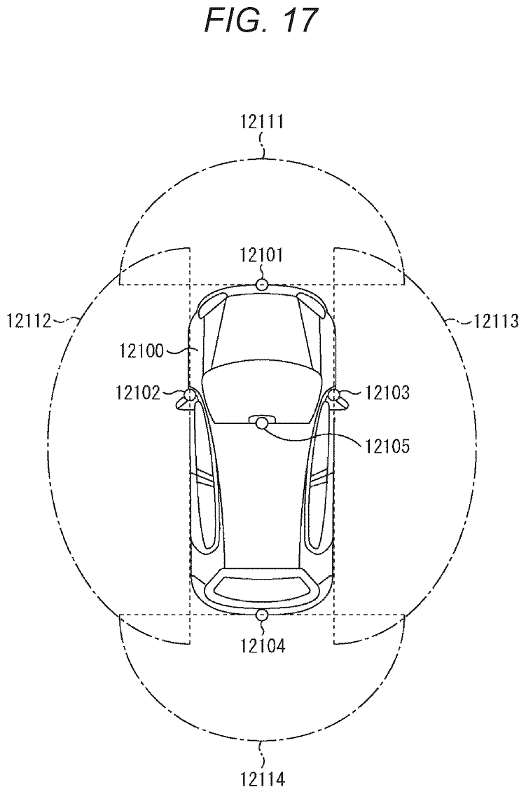

FIG. 17 is a diagram illustrating an example of an installation position of the imaging section 12031.

In FIG. 17, the imaging section 12031 includes imaging sections 12101, 12102, 12103, 12104, and 12105.

The imaging sections 12101, 12102, 12103, 12104, and 12105 are provided at positions, for example, a front nose, sideview mirrors, a rear bumper, and a back door of the vehicle 12100, an upper portion of a windshield within the interior of the vehicle, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 17 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure can be applied has been described above. The technology according to the present disclosure is applicable to the imaging section 12031, for example, among the configurations described above. Specifically, the imaging element 1 in FIG. 1 can be applied to the imaging section 12031. By applying the technology according to the present disclosure to the imaging section 12031, an output signal amount proportional to an exposure time can be obtained and a captured image that is easier to view can be obtained, and thus fatigue of the driver can be reduced.

Note that the embodiments described above show examples for embodying the present technology, and the matters in the embodiments and the matters specifying the invention in the claims have corresponding relationships, respectively. Similarly, the matters specifying the invention in the claims and matters with the same names in the embodiments of the present technology have correspondence relationships, respectively. However, the present technology is not limited to the embodiments, and can be embodied by applying various modifications to the embodiments without departing from the gist of the present technology.

Note that effects described in the present specification are merely examples and are not limited, and other effects may be provided.

### 7. Configuration that can be Taken by Present Technology

Note that the present technology can also take the following configurations.

(1) An imaging element including:
a first pixel block having a plurality of pixels including color filters of a same first color; and
a second pixel block having a plurality of pixels including color filters of a same second color that is different from the first pixel block, the number of pixels of the second pixel block being different from the number of pixels of the first pixel block,
in which the first pixel block and the second pixel block each have a plurality of pixel pairs each including two pixels,
a plurality of lenses is provided at positions corresponding to the plurality of pixel pairs,
the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels,
the imaging element further includes
a signal amount adjustment unit that adjusts output signal amounts output from the pixels of the first pixel block and the second pixel block, and
the signal amount adjustment unit adjusts the output signal amounts so that an output signal amount concerning the first color output from the first pixel block and an output signal amount concerning the second color output from the second pixel block match.

(2) The imaging element according to (1), in which

the signal amount adjustment unit adjusts the output signal amount concerning the first color output from the first pixel block and the output signal amount concerning the second color output from the second pixel block so that a smaller one of the output signal amounts matches a larger one of the output signal amounts.

(3) The imaging element according to (2), in which

in a first drive mode in which signals of the pixels of the first pixel block and the second pixel block are individually read and a second drive mode in which signals of the two pixels of the pixel pair are added and the added signals are read, the signal amount adjustment unit adjusts the output signal amounts so that the output signal amount concerning the second color output from the second pixel block matches the output signal amount concerning the first color output from the first pixel block.

(4) The imaging element according to (2), in which

in a third drive mode in which signals of all the pixels of the first pixel block and the second pixel block are added and the added signals are read, the signal amount adjustment unit adjusts the output signal amounts so that the output signal amount concerning the first color output from the first pixel block matches the output signal amount concerning the second color output from the second pixel block.

(5) The imaging element according to (1), in which

the signal amount adjustment unit adjusts the output signal amounts by digital gain adjustment in a digital region after conversion of an analog signal output from each of the pixels of the first pixel block and the second pixel block into a digital signal.

(6) The imaging element according to (1), in which

the signal amount adjustment unit adjusts the output signal amounts of the colors by analog gain adjustment in an analog region before conversion of an analog signal output from each of the pixels of the first pixel block and the second pixel block into a digital signal.

(7) The imaging element according to (6), in which
an analog-digital conversion unit that converts an analog signal into a digital signal is a single-slope analog-digital conversion unit that uses, as a signal for reference in analog-digital conversion, a reference signal of a ramp wave whose level changes at a predetermined slope with passage of time, and
the signal amount adjustment unit performs the analog gain adjustment by changing the slope of the reference signal of the ramp wave.

(8) The imaging element according to (1), in which
the two pixels are arranged side by side in a first direction, and
in each of the first pixel block and the second pixel block, two of the pixel pairs that are arranged in a second direction intersecting the first direction are arranged to be shifted in the first direction.

(9) An imaging element including:
a first pixel block having a plurality of pixels including color filters of a same first color;
a second pixel block having a plurality of pixels including color filters of a same second color that is different from the first pixel block, the number of pixels of the second pixel block being different from the number of pixels of the first pixel block; and
an analog-digital conversion unit that converts an analog signal output from each pixel of the first pixel block and the second pixel block into a digital signal,
in which the first pixel block and the second pixel block each have a plurality of pixel pairs each including two pixels,
a plurality of lenses is provided at positions corresponding to the plurality of pixel pairs,
the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels,
the analog-digital conversion unit is a single-slope analog-digital conversion unit that uses, as a signal for reference in analog-digital conversion, a reference signal of a ramp signal given from a reference signal generation unit,
a plurality of reference signal generation units that generate reference signals of ramp waves having different slopes are provided as the reference signal generation unit,
the imaging element further includes
a signal amount adjustment unit that adjusts output signal amounts output from the pixels of the first pixel block and the second pixel block, and
the signal amount adjustment unit adjusts the output signal amounts so that an output signal amount concerning the first color output from the first pixel block and an output signal amount concerning the second color output from the second pixel block match on the basis of the reference signals of the ramp waves having the different slopes generated by the plurality of reference signal generation units.

(10) The imaging element according to (9), in which

the plurality of reference signal generation units includes a reference signal generation unit for adjusting the output signal amount concerning the first color output from the first pixel block and a reference signal generation unit for adjusting the output signal amount concerning the second color output from the second pixel block.

(11) An electronic apparatus including an imaging element including:
a first pixel block having a plurality of pixels including color filters of a same first color, and
a second pixel block having a plurality of pixels including color filters of a same second color that is different from the first pixel block, the number of pixels of the second pixel block being different from the number of pixels of the first pixel block,
in which the first pixel block and the second pixel block each have a plurality of pixel pairs each including two pixels,
a plurality of lenses is provided at positions corresponding to the plurality of pixel pairs,
the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels,
the imaging element further includes
a signal amount adjustment unit that adjusts output signal amounts output from the pixels of the first pixel block and the second pixel block, and
the signal amount adjustment unit adjusts the output signal amounts so that an output signal amount concerning the first color output from the first pixel block and an output signal amount concerning the second color output from the second pixel block match.

### REFERENCE SIGNS LIST

1 Imaging element
11 Pixel array unit
12 Drive unit
13 Readout unit
14 Reference signal generation unit
15 Signal processing unit
16 Memory unit
17 Imaging control unit
18 Data receiving and rearranging unit
20 Pixel
21 Photoelectric conversion unit (photodiode)
22 Transfer transistor
23 Charge-voltage conversion unit
24 Reset transistor
25 Amplification transistor 25
26 Selection transistor
41, 43, 44 Semiconductor substrate
50 Signal amount adjustment unit
51 Color-specific digital gain correction processing unit
90 Pixel pair
100 (100R, 100Gr, 100Gb, 100B) Pixel block

1. An imaging element comprising:
a first pixel block having a plurality of pixels including color filters of a same first color; and
a second pixel block having a plurality of pixels including color filters of a same second color that is different from the first pixel block, the number of pixels of the second pixel block being different from the number of pixels of the first pixel block,
wherein the first pixel block and the second pixel block each have a plurality of pixel pairs each including two pixels,
a plurality of lenses is provided at positions corresponding to the plurality of pixel pairs,
the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels,
the imaging element further comprises
a signal amount adjustment unit that adjusts output signal amounts output from the pixels of the first pixel block and the second pixel block, and
the signal amount adjustment unit adjusts the output signal amounts so that an output signal amount concerning the first color output from the first pixel block and an output signal amount concerning the second color output from the second pixel block match.

2. The imaging element according to claim 1, wherein
the signal amount adjustment unit adjusts the output signal amount concerning the first color output from the first pixel block and the output signal amount concerning the second color output from the second pixel block so that a smaller one of the output signal amounts matches a larger one of the output signal amounts.

3. The imaging element according to claim 2, wherein
in a first drive mode in which signals of the pixels of the first pixel block and the second pixel block are individually read and a second drive mode in which signals of the two pixels of the pixel pair are added and the added signals are read, the signal amount adjustment unit adjusts the output signal amounts so that the output signal amount concerning the second color output from the second pixel block matches the output signal amount concerning the first color output from the first pixel block.

4. The imaging element according to claim 2, wherein
in a third drive mode in which signals of all the pixels of the first pixel block and the second pixel block are added and the added signals are read, the signal amount adjustment unit adjusts the output signal amounts so that the output signal amount concerning the first color output from the first pixel block matches the output signal amount concerning the second color output from the second pixel block.

5. The imaging element according to claim 1, wherein
the signal amount adjustment unit adjusts the output signal amounts by digital gain adjustment in a digital region after conversion of an analog signal output from each of the pixels of the first pixel block and the second pixel block into a digital signal.

6. The imaging element according to claim 1, wherein
the signal amount adjustment unit adjusts the output signal amounts of the colors by analog gain adjustment in an analog region before conversion of an analog signal output from each of the pixels of the first pixel block and the second pixel block into a digital signal.

7. The imaging element according to claim 6, wherein
an analog-digital conversion unit that converts an analog signal into a digital signal is a single-slope analog-digital conversion unit that uses, as a signal for reference in analog-digital conversion, a reference signal of a ramp wave whose level changes at a predetermined slope with passage of time, and
the signal amount adjustment unit performs the analog gain adjustment by changing the slope of the reference signal of the ramp wave.

8. The imaging element according to claim 1, wherein
the two pixels are arranged side by side in a first direction, and
in each of the first pixel block and the second pixel block, two of the pixel pairs that are arranged in a second direction intersecting the first direction are arranged to be shifted in the first direction.

9. An imaging element comprising:
a first pixel block having a plurality of pixels including color filters of a same first color;
a second pixel block having a plurality of pixels including color filters of a same second color that is different from the first pixel block, the number of pixels of the second pixel block being different from the number of pixels of the first pixel block; and
an analog-digital conversion unit that converts an analog signal output from each pixel of the first pixel block and the second pixel block into a digital signal,
wherein the first pixel block and the second pixel block each have a plurality of pixel pairs each including two pixels,
a plurality of lenses is provided at positions corresponding to the plurality of pixel pairs,
the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels,
the analog-digital conversion unit is a single-slope analog-digital conversion unit that uses, as a signal for reference in analog-digital conversion, a reference signal of a ramp wave given from a reference signal generation unit,
a plurality of reference signal generation units that generate reference signals of ramp waves having different slopes are provided as the reference signal generation unit,
the imaging element further comprises
a signal amount adjustment unit that adjusts output signal amounts output from the pixels of the first pixel block and the second pixel block, and
the signal amount adjustment unit adjusts the output signal amounts so that an output signal amount concerning the first color output from the first pixel block and an output signal amount concerning the second color output from the second pixel block match on a basis of the reference signals of the ramp waves having the different slopes generated by the plurality of reference signal generation units.

10. The imaging element according to claim 9, wherein
the plurality of reference signal generation units includes a reference signal generation unit for adjusting the output signal amount concerning the first color output from the first pixel block and a reference signal generation unit for adjusting the output signal amount concerning the second color output from the second pixel block.

11. An electronic apparatus comprising an imaging element including:
a first pixel block having a plurality of pixels including color filters of a same first color, and
a second pixel block having a plurality of pixels including color filters of a same second color that is different from the first pixel block, the number of pixels of the second pixel block being different from the number of pixels of the first pixel block,
wherein the first pixel block and the second pixel block each have a plurality of pixel pairs each including two pixels,
a plurality of lenses is provided at positions corresponding to the plurality of pixel pairs,
the first pixel block and the second pixel block each have a pixel-sharing configuration in which a charge-voltage conversion unit that converts a charge obtained in a photoelectric conversion unit into a voltage and succeeding pixel constituent elements are shared among a plurality of pixels,
the imaging element further includes
a signal amount adjustment unit that adjusts output signal amounts output from the pixels of the first pixel block and the second pixel block, and
the signal amount adjustment unit adjusts the output signal amounts so that an output signal amount concerning the first color output from the first pixel block and an output signal amount concerning the second color output from the second pixel block match.
